(19) United States
(12) Patent Application Publication
(10) Pub. No.: US 2026/0362871 A1
(43) Pub. Date: Nov. 12, 2026

(54) METHOD FOR MANUFACTURING MICRODISPLAY PANEL

(71) Applicant: WAVELORD CO., LTD, Hwaseong-si (KR)

(72) Inventors: Juneo SONG, Suwon-si (KR); Ji Hyung MOON, Gunpo-si (KR); Hyeong Seon YUN, Paju-si (KR); Tae Kyoung KIM, Osan-si (KR)

(73) Assignee: WAVELORD CO., LTD, Hwaseong-si (KR)

(21) Appl. No.: 19/405,521

(22) Filed: Dec. 2, 2025

(30) Foreign Application Priority Data
Dec. 6, 2024 (KR) 10-2024-0180700
Mar. 5, 2025 (KR) 10-2025-0028099

(51) Int. Cl. H10H 29/03; H10H 20/01; H10H 29/01

(52) U.S. Cl. CPC H10H 29/03; H10H 20/018; H10H 29/012

(57) ABSTRACT

The present invention relates to a method for manufacturing a microdisplay panel, and includes: a preparation operation of preparing light-emitting diode (LED) dies, a back wafer having a plurality of complementary metal-oxide-semiconductor (CMOS) panel electrode dies, and a masking wafer having a plurality of masking holes formed therein; a bonding operation of bonding the masking wafer to the back wafer; an alignment operation of aligning and bonding the plurality of LED dies onto the plurality of CMOS panel electrode dies using the masking holes of the masking wafer; and a removal operation of removing the masking wafer. According to the present invention, since alignment constraints can be easily avoided by using an LED die and a masking wafer when manufacturing an LEDoS microdisplay panel, there are effects of significantly improving the performance, quality, and mass production yield of a microdisplay panel.

### CROSS-REFERENCE TO RELATED APPLICATION

This application claims priority to and the benefit of Korean Patent Application No. 10-2024-0180700, filed on Dec. 6, 2024, and Korean Patent Application No. 10-2025-0028099, filed on Mar. 5, 2025, the disclosure of which is incorporated herein by reference in its entirety.

### BACKGROUND

### 1. Field of the Invention

The present invention relates to a method for manufacturing a microdisplay panel, and more particularly, to a method for manufacturing a microdisplay panel capable of avoiding alignment constraints by using a light-emitting diode (LED) die and a masking wafer when manufacturing an LED on silicon (LEDoS) microdisplay panel.

### 2. Discussion of Related Art

The types of implementation of the metaverse, which has recently been attracting attention, are classified into four types such as virtual reality (VR), augmented reality (AR), mixed reality (MR), and extended reality (XR). It is expected that the metaverse ecosystem will develop in the future, focusing on XR, which is a reality that combines VR, AR, and MR among these metaverses. In addition, in order to implement this effectively, devices (smart glasses, head-mounted displays, and the like) that include microdisplays with a diagonal length of less than one inch as a core component, along with software for next-generation computing platforms that can deliver innovative user experiences, are required. Particularly, the development of high-performance microdisplay panel technology is absolutely necessary to provide XR users with the greatest immersion, visibility, and convenience and minimize dizziness.

As shown in FIG. 1, a conventional microdisplay panel 10 corresponds to a technology that combines a silicon complementary metal-oxide-semiconductor (Si CMOS) semiconductor wafer process and a high-resolution, high-brightness, ultra-small display process, and the conventional microdisplay panel 10 may have a structure in which a Si CMOS wafer 11 that has a (100) crystal plane of 4″ or more and includes a plurality of CMOS panel electrode dies 12, a plurality of microLED electrode pads 14, and a transparent wafer 13 of 4″ or more that includes a plurality of microLED chips 15 are bonded through conductive bonding 16. Meanwhile, the types of microdisplay panels expected to be applied to XR devices include liquid crystal (LC)-based LC on Si (LCoS), organic light-emitting diode (OLED)-based OLED on Si (OLEDoS), and ultra-small microLED-based LED on Si (LEDoS) with a pixel size of less than 5 μm. In addition, in the case of VR, where displays with a low pixel density are applied, the microdisplay panels are being developed and mass-produced mainly based on LCoS and OLEDoS.

However, with the advancement of metaverse implementation technology, the need for lightweight AR, MR, and XR devices to which microdisplay panels with a high pixel density are applied is gradually increasing. In addition, although the development of LEDoS technology, which is considered an ideal solution in theory based on its superior inorganic properties, is urgently needed to satisfy these needs, a microdisplay panel platform for this has not yet been established.

LEDoSs based on ultra-small microLEDs with pixel sizes of less than 5 μm have the advantages of an excellent power-to-performance ratio (P/P) and a short response speed when applied to XR devices, and there are the advantages that the LEDoSs are composed of inorganic materials and thus have a long lifespan, and have efficient power use to reduce heat generation and enable long-term battery life. Particularly, since XR devices have a very short distance between the display and the eyes, even a slight delay in image conversion can easily cause discomfort such as dizziness. Thus, LEDoS, which has a nanosecond response speed, is considered to be the most suitable for XR devices compared to LCoS and OLEDoS, which have a microsecond response speed.

Furthermore, it is evaluated that the biggest reason why LEDoS is attracting attention in AR, MR, and XR devices, unlike VR, is due to its brightness and luminous efficiency. Since smart glasses can be worn regardless of location, high brightness is essential for normal operation even in outdoor environments such as sunlight. In theory, microLEDs support brightness of tens to millions of nits, and since OLEDs are made of organic materials, whereas microLEDs are made of inorganic materials, the microLEDs also have the advantage of high luminous efficiency.

However, despite the above-described advantages, the biggest reason why LEDoSs based on ultra-small microLEDs with pixel sizes of less than 5 μm have not been established as a major component of XR devices is the difficulty in mass production. That is, since the LEDoS requires millions of ultra-small microLEDs to be fixed on a Si CMOS wafer, the process difficulty is high and the yield is very low, which leads to increased manufacturing costs and high component prices. This is reflected in the final consumer price, and it is difficult to satisfy market demand as LEDoS is supplied as a high-priced XR device.

Meanwhile, as shown in FIG. 2, the development of LEDoS to which group III-V compound (GaN, GaP, and the like) microLED light sources are applied has been in progress until recently through traditional approaches such as (1) monolithic integration of wafers (or unit dies) including microLED arrays on CMOS wafers or (2) hybridization between wafers (or unit dies) on blue, green, and red light source wafers (or unit dies) on which CMOS wafers or microLED arrays are fabricated.

One of the biggest obstacles to the development of LEDoS to which blue, green, and red microLED light sources including group III-V compounds are applied is the difficulty in securing a solution for pixels smaller than 5 μm. In addition, recently, 5 μm-level pixels have been successfully demonstrated using monolithic integration technology, and some demonstrators developed based on hybridization technology were fabricated using sapphire flip chips, achieving 10 μm-level pixels. Additionally, it has been demonstrated that it is possible to reduce pixels to the 5 μm level in the same way by using micro tube wiring in hybridization technology. However, both monolithic integration and hybridization technologies are impractical solutions with significant challenges in mass production in terms of quality and yield, making mass production difficult.

The above-described monolithic integration technology and hybridization technology have a common feature of separately designing and manufacturing a front plane wafer including a group III-V compound microLED array and a Si CMOS back plane wafer including numerous IC electrode pad arrays, and then assembling these wafers. However, the microLED array manufactured at the unit die level or wafer level on the Si CMOS wafer needs to be ultra-finely aligned regardless of the method. Thus, in this case, alignment is limited to the precision of the process-related device, which has a significant impact on the pixel and inter-pixel distance (pitch) limitations, and mass production also becomes difficult. Accordingly, a new alternative solution that is capable of overcoming the above-described ultra-fine alignment constraints is required to manufacture LEDoS to which high-resolution, high-brightness, and high-speed operating blue, green, and red microLED light sources with pixels of less than 5 μm and pitches of less than 3 μm are applied.

Accordingly, although several impressive demonstrations with 6 μm pixels have been recently released using engineering monolithic epitaxy wafers manufactured through a low-temperature metal bonding process between a Si CMOS wafer and a microLED array wafer, mass production is considered impossible due to low quality and yield issues caused by low-temperature metal bonding and the use of small-diameter wafers of less than 6 inches. Above all, when fabricating ultra-fine pixels of less than 3 μm for microdisplays using conventional engineering monolithic epitaxy wafers using metal bonding, the patterning etching process faces even greater difficulties.

As another example, great progress has been made in solving the problem of limitations in the brightness and resolution of LEDoS to which group III-V compound microLED light sources are recently applied, and a novel engineering monolithic epitaxy wafer approach has been proposed that can provide high-volume, low-cost manufacturing solutions using 12-inch large-diameter Si CMOS wafers.

As shown in FIG. 3, the corresponding technology is specifically performed through the following four-step process using an engineering monolithic epitaxy wafer. (1) First, an LED epitaxy cut to a predetermined size (for example, 4 mm×6 mm) is aligned and bonded at a unit die level on a 12-inch large-diameter Si blanket wafer using an LED epitaxy wafer. Afterward, the growth wafer and buffer layer of the LED epitaxy are removed and then planarized to leave only an LED active layer of a predetermined thickness (for example, approximately 1.5 μm) on the large-diameter Si blanket wafer, and then the LED FAB process in the form of a pixel chip is completed. (2) Subsequently, the Si blanket wafer with the completed pixel chip is bonded to a 12-inch CMOS IC Si wafer at the wafer level through multi-layer metal bonding. (3) Subsequently, the Si blanket wafer is removed. (4) Subsequently, the remaining process is finally performed on the CMOS IC Si wafer for the microLED array that functions as a pixel.

However, in step (1), when bonding the LED epitaxy unit die on the Si blanket wafer, there is a limitation that the alignment needs to be performed on a CMOS IC Si wafer of the same size to bond the LED epitaxy unit die on the Si blanket wafer. In addition, in step (2), when bonding with a multi-layer metal including a low-melting-point metal (Sn or In), there is a problem in that a phenomenon of overflowing low-melting-point metal components occurs relatively easily, resulting in a short circuit defect that is electrically connected between the microLED sub-pixel arrays in the panel or with the adjacent CMOS IC electrode pad array. Furthermore, in step (2), there is a problem that defects occur due to the difficulty in ultra-fine alignment wafer bonding between the Si blanket wafer (that is, front plane wafer) and the CMOS IC Si wafer due to the optically opaque nature of the Si blanket wafer and the multi-layer metal bonding layer. Here, the ultra-fine alignment means aligning the microLED array, which is a plurality (hundreds to tens of millions) of ultra-small pixel chips provided on a Si blanket wafer, and the CMOS IC electrode pad array provided on a CMOS IC Si wafer in a 1:1 manner.

That is, although the engineering monolithic epitaxy wafer approach presented in the above-described technologies is evaluated to provide a solution that brings us one step closer to the implementation of LEDoS based on ultra-small microLEDs with pixel sizes of less than 5 μm, since there are quality and yield issues caused by the use of metals (low temperature, multi-layer) in wafer bonding, and it is very difficult to manufacture high-resolution microdisplays with ultra-fine pixels smaller than 3 μm, and there are also problems with some alignment processes, new alternatives are needed.

### RELATED ART DOCUMENTS

### Patent Document

(Patent Document 0001) Korea Patent Publication No. 10-2018-0009116

### SUMMARY OF THE INVENTION

The present invention is direct to providing a method for manufacturing a microdisplay panel capable of avoiding alignment constraints by using a light-emitting diode (LED) die and a masking wafer when manufacturing an LED on silicon (LEDoS) microdisplay panel.

According to an aspect of the present invention, there is provided a method for manufacturing a microdisplay panel that includes: a preparation operation of preparing an LED die, a back wafer having a plurality of complementary metal-oxide-semiconductor (CMOS) panel electrode dies, and a masking wafer having a plurality of masking holes formed therein; a bonding operation of bonding the masking wafer to the back wafer; an alignment operation of aligning and bonding a plurality of LED dies onto the plurality of CMOS panel electrode dies using the masking holes of the masking wafer; and a removal operation of removing the masking wafer.

Also, the method for manufacturing a microdisplay panel may further include, after the removal operation, a fabrication (FAB) operation of removing a support substrate of the LED die and forming a device structure for each pixel unit.

Furthermore, in the alignment operation, after pretreating the back wafer, the LED die may be aligned and bonded onto the back wafer.

In addition, a size of the masking hole may be greater than or equal to a size of the LED die.

According to another aspect of the present invention, there is provided a method for manufacturing a microdisplay panel that includes: a preparation operation of preparing an LED die, a blanket wafer, a back wafer including a plurality of CMOS panel electrode dies, and a masking wafer having a plurality of masking holes formed therein; a first bonding operation of bonding the masking wafer to the blanket wafer; an alignment operation of aligning and bonding a plurality of LED dies onto the blanket wafer using the masking holes of the masking wafer; a first removal operation of removing the masking wafer; a second bonding operation of aligning the plurality of the LED dies onto the plurality of CMOS panel electrode dies by bonding the blanket wafer, on which the plurality of LED dies are aligned, to the back wafer; and a second removal operation of removing the blanket wafer.

Also, the method for manufacturing a microdisplay panel may further include, after the second removal operation, a FAB operation of removing a support substrate of the LED die and forming a device structure for each pixel unit.

Furthermore, in the alignment operation, after pretreating the blanket wafer, the LED die may be aligned and bonded onto the blanket wafer, and in the first bonding operation, after pretreating at least one of the blanket wafer and the back wafer, the blanket wafer may be bonded to the back wafer.

In addition, a size of the masking hole may be greater than or equal to a size of the LED die.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows the structure of a conventional microdisplay panel;

FIG. 2 shows a conventional light-emitting diode on silicon (LEDoS) development approach;

FIG. 3 shows an approach using a conventional engineering monolithic epitaxy wafer;

FIG. 4 is a flowchart of a method for manufacturing a microdisplay panel according to a first embodiment of the present invention;

FIG. 5 shows a process of manufacturing a microdisplay panel according to the method for manufacturing a microdisplay panel according to the first embodiment of the present invention;

FIG. 6 is a flowchart of a method for manufacturing a microdisplay panel according to a second embodiment of the present invention;

FIG. 7 shows a process of manufacturing a microdisplay panel according to the method for manufacturing a microdisplay panel according to the second embodiment of the present invention; and

FIGS. 8 and 9 show examples of LED dies in the method for manufacturing a microdisplay panel according to the first embodiment or the second embodiment of the present invention.

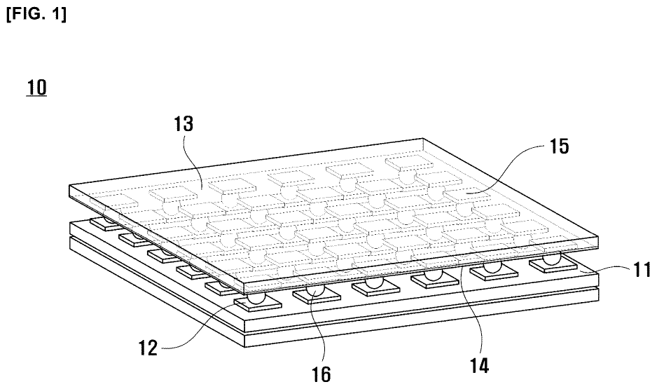

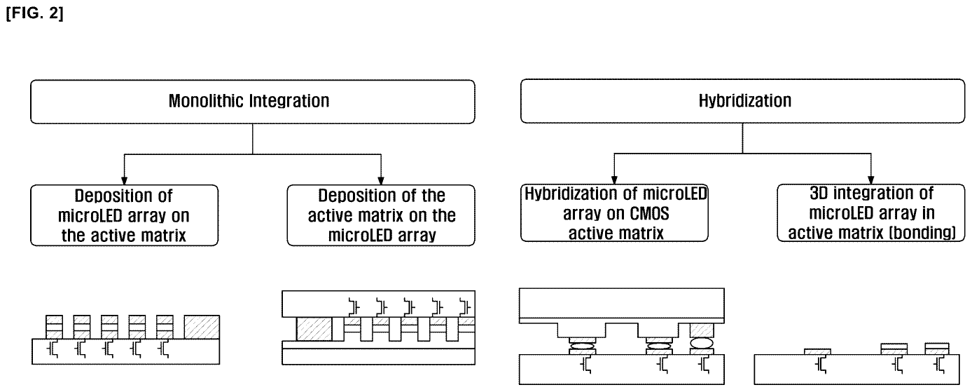

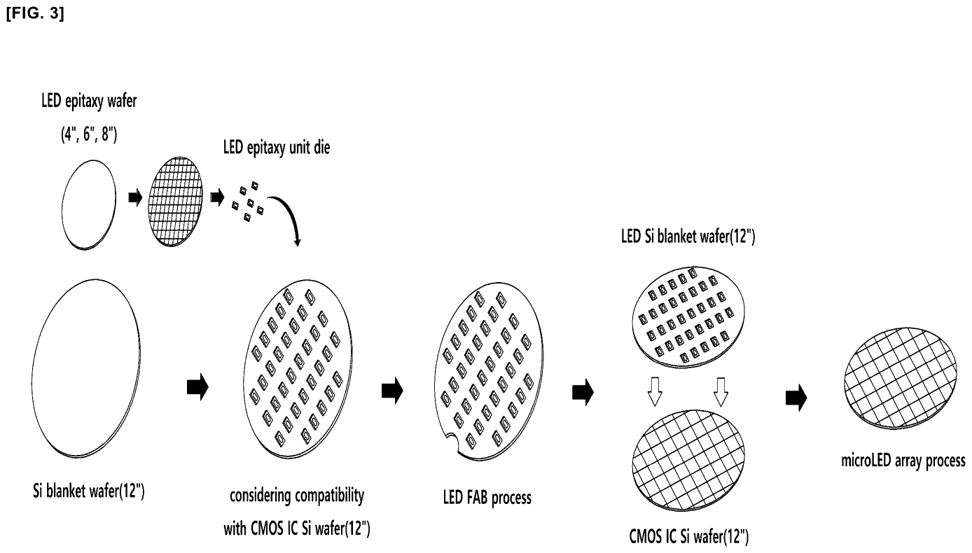

### DETAILED DESCRIPTION OF EXEMPLARY EMBODIMENTS

Hereinafter, some embodiments of the present invention will be described in detail through exemplary drawings. When assigning reference numerals to components of each of the drawings, it should be noted that identical components are denoted by the same reference numerals as much as possible even when they are shown on different drawings.

In addition, when describing embodiments of the present invention, when a detailed description of a related known configuration or function is determined to hinder understanding of the embodiment of the present invention, the detailed description is omitted.

Additionally, when describing components of embodiments of the present invention, terms such as first, second, A, B, (a), (b), and the like may be used. These terms are only intended to distinguish the components from other components, and the nature, order, or sequence of the components are not limited by the terms.

Hereinafter, a method S100 of manufacturing a microdisplay panel according to a first embodiment of the present invention will be described in detail with reference to the attached drawings.

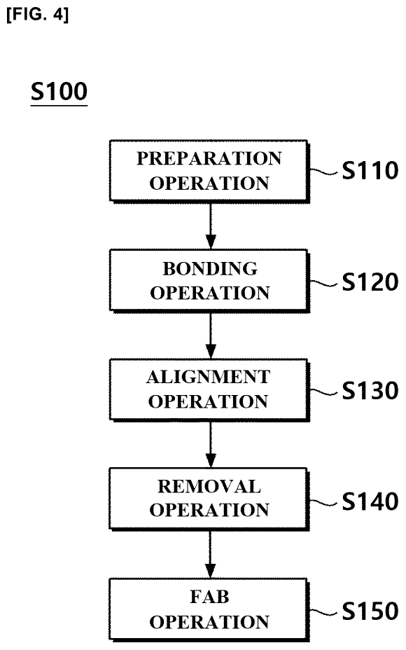

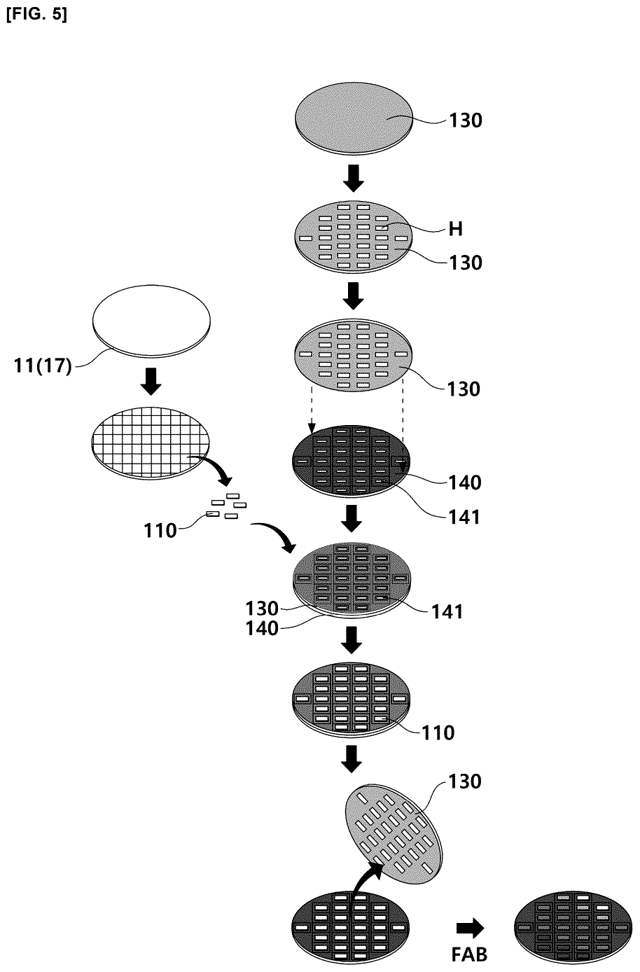

FIG. 4 is a flowchart of the method S100 of manufacturing a microdisplay panel according to the first embodiment of the present invention, and FIG. 5 shows a process of manufacturing a microdisplay panel according to the method S100 of manufacturing a microdisplay panel according to the first embodiment of the present invention.

As shown in FIGS. 4 and 5, the method S100 of manufacturing a microdisplay panel according to the first embodiment of the present invention may include a preparation operation S110, a bonding operation S120, an alignment operation S130, a removal operation S140, and a fabrication (FAB) operation S150.

The preparation operation S110 is an operation of preparing a light-emitting diode (LED) die 110, a back wafer 140, and a masking wafer 130.

First, in the present invention, the LED die 110 corresponds to a concept including an LED epitaxy die and an LED chip die, and it is preferable that a size of the LED die 110 is formed to be greater than a size of a CMOS panel electrode die 141 described below, and for example, the LED die 10 may be formed to have a diagonal length exceeding 1 inch. Particularly, in the present invention, a semi-finished light source die having the following characteristics and capable of sorting is defined as an epitaxy die of the present invention.

First, unlike a conventional chip die in which both electrodes, that is, a positive electrode and a negative electrode, are exposed to the outside, the epitaxy die of the present invention has a structure in which no electrodes are exposed or only one electrode is exposed to the outside. Accordingly, the epitaxy die of the present invention is not electrically sorted through an electroluminescence (EL, electric field application) measurement method, but may be optically sorted through a high-speed photoluminescence (PL, light energy application) measurement method so that a defective die (NG) is quickly and easily primarily determined using only optical characteristics (wavelength, half-maximum width, intensity, and the like).

Second, the epitaxy die of the present invention undergoes a process of forming a positive ohmic contact electrode (p-ohmic contact electrode) and/or a negative ohmic contact electrode (n-ohmic contact electrode) requiring a high-temperature heat treatment of 300 °C or higher that is completed in the epitaxy die manufacturing operation. Accordingly, the epitaxy die of the present invention has an advantage in that a high-temperature heat treatment process is not required after transfer to the back wafer 140.

Third, the epitaxy die of the present invention has a sapphire support substrate (or a Si support substrate) attached thereto, which is removed after transfer. Accordingly, there is an advantage in that the positional movement of chip dies is possible collectively or individually (selectively) through conventional chip die transfer processes such as pick & place and replace.

That is, in the present invention, when the epitaxy die has a structure in which electrodes are not exposed or only one electrode is exposed to the outside, the epitaxy die may be defined as an LED epitaxy die, and when both the positive electrode and the negative electrode are exposed to the outside, the epitaxy die may be defined as an LED chip die.

The preparation operation S110 is an operation of manufacturing the above-described LED die 110 (LED epitaxy die or LED chip die), and may include an operation of forming a light-emitting portion 12, an operation of forming ohmic contact electrodes 13 and 14, an operation of manufacturing the LED die 110 by separating a support substrate 17 (growth substrate 11 when the growth substrate 11 is not removed) into preset die units, and an operation of sorting the manufactured LED die 110 according to whether the LED die 110 is defective.

First, in the operation of forming the light-emitting portion 12, the light-emitting portion 12 is epitaxially grown on an initial growth substrate 11. Here, the initial growth substrate 11 may be prepared as a growth substrate 11 having a size such as 4″, 6″, or 8″, and a sapphire (α-phase Al2O3) growth substrate 11, a Si growth substrate 11, or a GaAs growth substrate 11, which is optically transparent and has high-temperature resistance, and theoretically transmits 100% of a laser beam (single-wavelength light)without absorption may be prepared as the initial growth substrate 11 according to the light-emitting portion 12 to be grown, but the present invention is not limited thereto.

Meanwhile, in the present invention, the support substrate 17 may be the initial growth substrate 11 when the initial growth substrate 11 is not removed or may be a separate substrate bonded to remove the initial growth substrate 11.

In addition, the light-emitting portion 12 may include a first semiconductor region (for example, a p-type semiconductor region), an active region (for example, multi quantum wells (MQWs)), and a second semiconductor region (for example, an n-type semiconductor region), and the second semiconductor region, the active region, and the first semiconductor region may be sequentially epitaxially grown on the growth substrate 11 to emit blue light, green light, or red light.

When the light-emitting portion 12 emits blue light or green light, for example, binary, ternary, or quaternary compounds such as InN, InGaN, GaN, AlGaN, AlN, and AlGaInN, which are group III (Al, Ga, and In) nitride semiconductors among group III-V compound semiconductors, may be disposed in an appropriate position and order on the growth substrate 11 and epitaxially grown, and when the light-emitting portion 12 emits red light, for example, binary, ternary, or quaternary compounds such as InP, InGaP, GaP, AlInP, AlGaP, AlP, and AlGaInP, which are group III (Al, Ga, and In) phosphide semiconductors among group III-V compound semiconductors, may be disposed in an appropriate position and order on the growth substrate 11 and epitaxially grown, but are not limited thereto.

In the operation of forming the ohmic contact electrodes 13 and 14, at least one of a p-type ohmic contact electrode 13 and an n-type ohmic contact electrode 14 that are electrically connected to the above-described light-emitting portion 12 may be formed, and then heat treatment may be performed at a high temperature of 300 °C or higher.

In this case, in the present invention, the p-type ohmic contact electrode 13 is necessarily formed, and the n-type ohmic contact electrode 14 is selectively formed. When the n-type ohmic contact electrode 14 is to be formed, for example, the second semiconductor region may be exposed using mesa etching, or a surface of the second semiconductor region may be exposed using a separate temporary substrate and/or the support substrate 17, and then the n-type ohmic contact electrode 14 may be formed.

Additionally, the ohmic contact electrodes 13 and 14 may be basically formed of a material having high transparency and/or reflectance and excellent electrical conductivity, but are not limited thereto.

In the operation of manufacturing the LED die 110 by separating the support substrate 17 (growth substrate 11 when the growth substrate 11 is not removed) into preset die units, the LED die 110 may be manufactured by separating the support substrate 17 into preset die units using a known cutting technique. In this case, a size of the manufactured LED die 110 may be formed greater than a size of the CMOS panel electrode die 141.

Meanwhile, as described above, when the LED die 110 has a structure in which the electrodes of the manufactured LED die 110 are not exposed or only one electrode is exposed to the outside, the LED die 110 may be an LED epitaxy die, and when both the positive electrode and the negative electrode are exposed to the outside, the LED die 110 may be an LED chip die.

In the operation of sorting the manufactured LED die 110 according to whether the LED die 110 is defective, a photoluminescence (PL, light energy application) measurement method or an electroluminescence (EL, electric field application) measurement method may be used for the manufactured LED die 110.

In this case, when the manufactured LED die 110 is an LED epitaxy die, since both electrodes are not exposed or only one electrode is exposed to the outside, the presence of optical defects may be determined through the PL measurement method. When the manufactured LED die 110 is an LED chip die, since both the positive electrode and the negative electrode are exposed to the outside, both the PL measurement method and the EL measurement method may be used for determining the presence of optical and electrical defects.

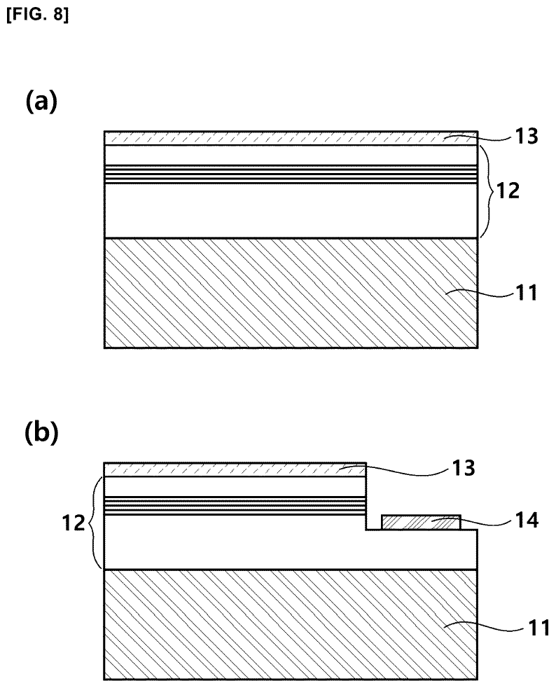

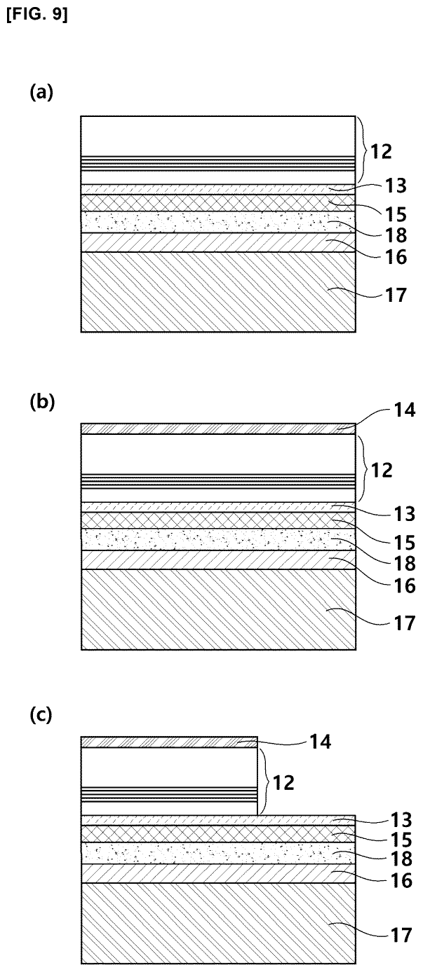

FIGS. 8 and 9 show examples of the LED die in the method for manufacturing a microdisplay panel according to the first embodiment of the present invention or an LED die in a method for manufacturing a microdisplay panel according to a second embodiment of the present invention.

When an example of the LED die 110 of the present invention is specifically described, FIG. 8A shows an LED die 110 that includes a growth substrate 11, a light-emitting portion 12, and a p-type ohmic contact electrode 13, has a structure in which only one electrode is exposed to the outside, and may correspond to an LED epitaxy die, and FIG. 8B shows an LED die 110 in which one side is mesa-etched and then the n-type ohmic contact electrode 14 is formed in the structure of the LED epitaxy die of FIG. 8A, and this structure, in which both electrodes are exposed to the outside, may correspond to an LED chip die.

In addition, FIG. 9A shows an LED die 110 in which a light-emitting portion 12, a p-type ohmic contact electrode 13, and a protective layer 15 are formed on the growth substrate 11, and then bonded to a support substrate 17 including a sacrificial isolation layer 16 through a bonding layer 18, and then the growth substrate 11 is removed to expose a surface of the second semiconductor region, and FIG. 9B shows an LED die 110 that further includes an n-type ohmic contact electrode 14, has a structure in which only one electrode is exposed to the outside, and may correspond to an LED epitaxy die. In addition, FIG. 9C shows an LED die 110 in which one side is mesa-etched in the structure of the LED epitaxy die of FIG. 9B to expose the p-type ohmic contact electrode 13, and this structure, in which both electrodes are exposed to the outside, may correspond to an LED chip die.

However, in the present invention, the LED die 110 is not limited to the above-described structures, and various structures that meet the definitions of the above-described epitaxy die or chip die may be adopted.

The back wafer 140 is an active driving integrated circuit (IC) driven by an active matrix (AM) method, and refers to a CMOS backplane wafer or a CMOS panel in which a plurality of CMOS panel electrode dies 141 are arranged in an array on an upper surface. A passivation layer may be formed on the upper surface of the back wafer 140 so that upper surfaces of the plurality of CMOS panel electrode dies 141 are not exposed, and a portion of the passivation layer may be etched so that the plurality of CMOS panel electrode dies 141 are exposed when the LED dies 110 are bonded, and a size of each of the bonded LED dies 110 may be formed to be greater than a size of each of the CMOS panel electrode dies 141. Meanwhile, although the back wafer 140 is a Si wafer having a (100) crystal plane and is a 4″, 8″, or 12″ Si wafer according to a standard CMOS IC process, the size of the back wafer 140 is not particularly limited.

The masking wafer 130 has a plurality of masking holes H formed therein to align and bond the LED die 110 on the back wafer 140. The masking wafer 130 may be formed of optically transparent sapphire, glass, quartz, or the like, and may be formed in a size corresponding to the back wafer 140 of 4″, 8″, 12″, or the like.

In this case, the plurality of masking holes H are formed to be arrayed in the same manner as the CMOS panel electrode dies 141 of the back wafer 140, and a size of each of the masking holes H may be formed to be greater than or equal to the size of the LED die 110.

Furthermore, an alignment key may be inserted into the masking wafer 130 for alignment with the back wafer 140, and a detaching layer may be deposited on one surface of the masking wafer 130 to facilitate removal from the back wafer 140 during the removal operation S140 described below. Materials such as SiO2, ZnO, ITO, transparent conductive oxides (TCOs), and transparent conductive nitrides (TCNs) may be used as materials for the detaching layer, but the present invention is not limited thereto.

The bonding operation S120 is an operation of bonding the masking wafer 130 to the back wafer 140.

Specifically, in the bonding operation S120, the masking wafer 130 and the back wafer 140 may be aligned so that each of the CMOS panel electrode dies 141 is disposed in each of the masking holes H, and bonded in a wafer-to-wafer (W2W) manner. The bonding method may include a surface activated bonding (SAB) method or a eutectic bonding method at low temperature or room temperature, and the bonding portion may be a front surface or outer edge of each wafer, but the present invention is not limited thereto.

The alignment operation S130 is an operation of aligning and bonding the plurality of LED dies 110 onto the plurality of CMOS panel electrode dies 141 using the masking holes H of the masking wafer 130.

In this case, in the alignment operation S130, the back wafer 140 may first be pretreated to improve bonding strength and reliability when bonding the LED die 110.

Specifically, in the alignment operation S130, the CMOS panel electrode die 141 of the back wafer 140 may be pretreated using plasma treatment, Ar neutron treatment, ultrathin metal film deposition, or the like. Here, when plasma treatment is used, oxides and organic contaminants on the surface of the CMOS panel electrode die 141 may be removed, and the surface may be made more chemically active to improve bonding strength. When Ar neutron treatment is used, a surface of the CMOS panel electrode die 141 may be irradiated with a high-energy Ar neutron beam to remove impurities and rearrange the crystal structure to improve bonding strength. When ultrathin metal film deposition is used, bonding strength may be improved by depositing an ultrathin metal film of In, Sn, Zn, or the like on the CMOS panel electrode die 141, but the present invention is not limited thereto.

Afterward, in the alignment operation S130, the LED die 110 may be bonded onto the CMOS panel electrode die 141 exposed through the masking hole H. Since the LED die 110 of the present invention has the support substrate 17 (growth substrate 11 when the growth substrate 11 is not removed) attached thereto, the LED die 110 may be bonded in a die to wafer (D2W) manner using pick & place or the like. In this case, in the present invention, since the alignment of the LED die 110 has already been achieved by the masking hole H, alignment constraints may be easily avoided when bonding the LED die 110 onto the back wafer 140.

In addition, the bonding method may include a surface activated bonding (SAB) method, a eutectic bonding method, or the like at low or room temperature, and after bonding, heat treatment may be performed in an oxygen atmosphere (O2-rich atmosphere) at a temperature that does not damage the CMOS circuit to enhance bonding strength.

The removal operation S140 is an operation of removing the masking wafer 130 from the back wafer 140.

Specifically, in the removal operation S140, when the masking wafer 130 includes the detaching layer, the masking wafer 130 may be removed using the detaching layer, and in the present invention, when the masking wafer 130 is formed of sapphire, glass, quartz, or the like, the masking wafer 130 may be removed using a laser lift off (LLO) technique. In this case, when the masking wafer 130 is removed in a non-destructive manner using the laser lift-off technique, since the masking wafer 130 may be used again, process costs are also expected to be reduced.

The FAB operation S150 is an operation of completing a microdisplay panel structure by removing each of the support substrates 17 of the LED dies 110 bonded to the CMOS panel electrode dies 141, performing a pixel fabrication (FAB) process, and forming a device structure for each pixel unit.

Specifically, in the FAB operation S150, the support substrate 17 (growth substrate 11 when the growth substrate 11 is not removed) of the LED die 110 bonded to the CMOS panel electrode die 141 may be separated and/or removed, and then a pixel FAB process including electrode formation, passivation layer formation, or the like may be performed to form a device structure for each pixel unit, thereby completing the microdisplay panel structure. In this case, even in the FAB operation S150, heat treatment may be performed in an oxygen atmosphere (O2-rich atmosphere) at a temperature that does not damage the circuit of the CMOS panel electrode die 141.

Meanwhile, in the present invention, the process of separating and/or removing the support substrate 17 of the LED die 110 may be performed either after the alignment operation S130 or after the removal operation S140, and this may be appropriately selected according to the structure of the LED die 110.

Hereinafter, a method S200 of manufacturing a microdisplay panel according to the second embodiment of the present invention will be described in detail with reference to the attached drawings.

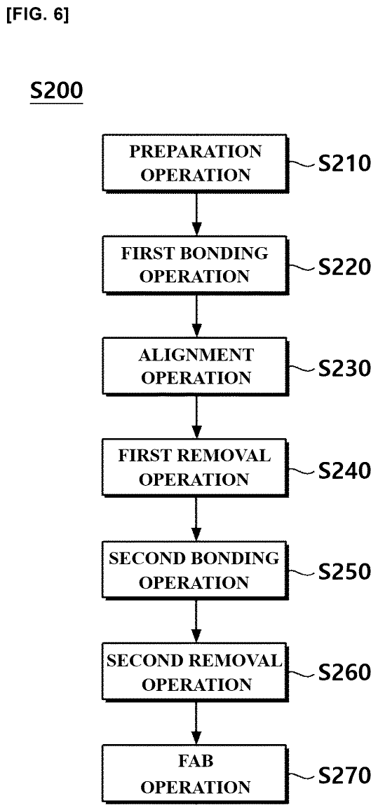

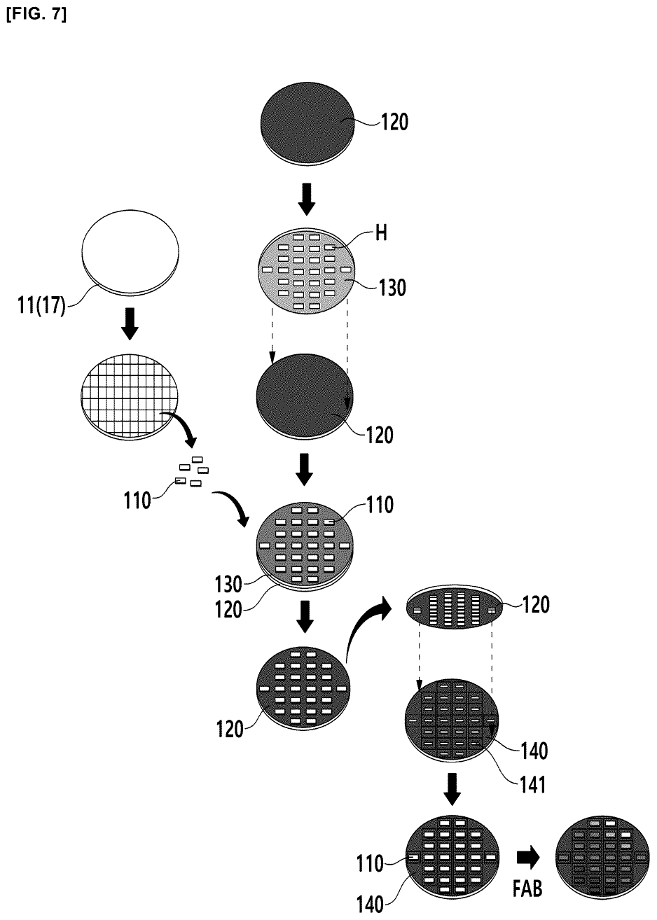

FIG. 6 is a flowchart for describing the method S200 of manufacturing a microdisplay panel according to the second embodiment of the present invention, and FIG. 7 shows a process in which a microdisplay panel is manufactured according to the method S200 of manufacturing a microdisplay panel according to the second embodiment of the present invention.

As shown in FIGS. 6 and 7, the method S200 of manufacturing a microdisplay panel according to the second embodiment of the present invention may include a preparation operation S210, a first bonding operation S220, an alignment operation S230, a first removal operation S240, a second bonding operation S250, a second removal operation S260, and a FAB operation S270.

Hereinafter, some contents that overlap with the method S100 of manufacturing a microdisplay panel according to the first embodiment of the present invention will be omitted.

The preparation operation S210 is an operation of preparing an LED die 110, a blanket wafer 120, a back wafer 140, and a masking wafer 130.

Here, since the contents of the LED die 110, the back wafer 140, and the masking wafer 130 are the same as those in the method for manufacturing a microdisplay panel according to the first embodiment of the present invention, a repeated description is omitted.

The blanket wafer 120 is used for aligning and bonding the LED die 110 onto the back wafer 140 in an auxiliary manner, and may be formed of sapphire (Al2O3), Si, or the like, and may be formed in a size corresponding to that of the back wafer 140, such as 4″, 8″, or 12.″

The first bonding operation S220 is an operation of bonding the masking wafer 130 to the blanket wafer 120.

Specifically, in the first bonding operation S220, the masking wafer 130 having a plurality of masking holes H formed therein and the blanket wafer 120 are aligned and bonded in a wafer-to-wafer (W2W) manner. The bonding method may include a surface activated bonding (SAB) method or a eutectic bonding method at low temperature or room temperature, and the bonding portion may be a front surface or outer edge of each wafer, but the present invention is not limited thereto.

The alignment operation S230 is an operation of aligning and bonding the plurality of LED dies 110 onto the blanket wafer 120 using the masking holes H of the masking wafer 130.

In this case, in the alignment operation S230, the blanket wafer 120 may first be pretreated to improve bonding strength and reliability when bonding the LED die 110.

Afterward, in the alignment operation S230, the LED die 110 may be bonded onto the blanket wafer 120 through the masking hole H. Since the LED die 110 of the present invention has the support substrate (growth substrate when the growth substrate is not removed) attached thereto, the LED die 110 may be bonded in a die to wafer (D2W) manner using pick & place, or the like. In this case, in the present invention, since the alignment of the LED die 110 has already been achieved by the masking hole H, alignment constraints may be easily avoided when bonding the LED die 110 onto the back wafer 140.

In addition, the bonding method may include a surface activated bonding (SAB) method or a eutectic bonding method at low or room temperature, and after bonding, heat treatment may be performed in an oxygen atmosphere (O2-rich atmosphere) at a temperature that does not damage the LED die 110 to enhance bonding strength.

The first removal operation S240 is an operation of removing the masking wafer 130 from the blanket wafer 120.

Specifically, in the first removal operation S240, when the masking wafer 130 includes a detaching layer, the masking wafer 130 may be removed using the detaching layer, and in the present invention, when the masking wafer 130 is formed of sapphire, glass, quartz, or the like, the masking wafer 130 may be removed using a laser lift off (LLO) technique.

The second bonding operation S250 is an operation of aligning and bonding the plurality of LED dies 110 onto the plurality of CMOS panel electrode dies 141 by bonding the blanket wafer 120, on which the plurality of LED dies 110 are aligned, to the back wafer 140.

Specifically, in the second bonding operation S250, the blanket wafer 120, on which the plurality of LED dies 110 are aligned, and the back wafer 140 are aligned and bonded in a wafer-to-wafer (W2W) manner. The bonding method may include a surface activated bonding (SAB) method or a eutectic bonding method at low temperature or room temperature, and the bonding portion may be a front surface or outer edge of each wafer, but the present invention is not limited thereto. In this case, in the present invention, since the LED dies 110 have already been aligned in the same manner as the CMOS panel electrode dies 141 through the masking holes H in the alignment operation S230, alignment constraint may be avoided, and thus the plurality of LED dies 110 may be easily aligned and disposed on the plurality of CMOS panel electrode dies 141.

Additionally, after the bonding, heat treatment may be performed in an oxygen atmosphere (O2-rich atmosphere) at a temperature that does not damage the LED die 110 to enhance bonding strength.

The second removal operation S260 is an operation of removing the blanket wafer 120 from the back wafer 140.

Specifically, in the second removal operation S260, when the blanket wafer 120 is formed of sapphire, the blanket wafer 120 may be removed using a laser lift off (LLO) technique, and when the blanket wafer 120 is formed of Si, the blanket wafer 120 may be removed using a chemical lift off (CLO) technique.

The FAB operation S270 is an operation of completing a microdisplay panel structure by separating and/or removing the support substrate 17 (growth substrate 11 when the growth substrate 11 is not removed) of the LED die 110 bonded to the CMOS panel electrode die 141, and performing a pixel fabrication (FAB) process to form a device structure for each pixel unit.

Meanwhile, in the present invention, the process of separating and/or removing the support substrate 17 of the LED die 110 may be performed after the alignment operation S230, after the first removal operation S240, after the second bonding operation S250, or after the second removal operation S260, and this may be appropriately selected according to the structure of the LED die 110.

According to the present invention, since alignment constraints can be easily avoided by using an LED die and a masking wafer when manufacturing an LEDoS microdisplay panel, there are effects of significantly improving the performance, quality, and mass production yield of a microdisplay panel.

Meanwhile, the effects of the present invention are not limited to the above-described effects, and various effects that are apparent to those skilled in the art from the following description may also be included.

In the above description, although all components constituting the embodiments of the present invention have been described as being combined or operating in combination as one, the present invention is not necessarily limited to such embodiments. That is, all of the components may be selectively combined to operate one or more times within the scope of the purpose of the present invention.

In addition, terms such as “comprise,” “include,” or “have” described above, unless specifically stated to the contrary, should be interpreted to mean that the corresponding component may be present, and thus should not be interpreted to exclude other components, but rather to include other components. All terms, including technical or scientific terms, have the same meaning as commonly understood by a person of ordinary skill in the art to which the present invention pertains, unless otherwise defined. Commonly used terms, such as terms defined in dictionaries, should be interpreted to be consistent with the contextual meaning of the related art, and shall not be interpreted in an ideal or overly formal sense, unless explicitly defined in the present invention.

Further, the above description is merely an example of the technical idea of the present invention, and those skilled in the art will appreciate that various modifications and variations can be made without departing from the essential characteristics of the present invention.

Accordingly, the embodiments disclosed in the present invention are intended to illustrate, rather than limit, the technical concept of the present invention, and the scope of the technical concept of the present invention is not limited by these embodiments. The scope of protection of the present invention should be interpreted by the following claims, and all technical concepts within the scope equivalent thereto should be construed as being included within the scope of the present invention.

What is claimed is:

1. A method for manufacturing a microdisplay panel, comprising:
a preparation operation of preparing a light-emitting diode (LED) die, a back wafer having a plurality of complementary metal-oxide-semiconductor (CMOS) panel electrode dies, and a masking wafer having a plurality of masking holes formed therein;
a bonding operation of bonding the masking wafer to the back wafer;
an alignment operation of aligning and bonding a plurality of LED dies onto the plurality of CMOS panel electrode dies using the masking holes of the masking wafer; and
a removal operation of removing the masking wafer.

2. The method of claim 1, further comprising, after the removal operation, a fabrication (FAB) operation of removing a support substrate of the LED die and forming a device structure for each pixel unit.

3. The method of claim 1, wherein, in the alignment operation, after pretreating the back wafer, the LED die is aligned and bonded onto the back wafer.

4. The method of claim 1, wherein a size of the masking hole is greater than or equal to a size of the LED die.

5. A method for manufacturing a microdisplay panel, comprising:
a preparation operation of preparing an LED die, a blanket wafer, a back wafer including a plurality of CMOS panel electrode dies, and a masking wafer having a plurality of masking holes formed therein;
a first bonding operation of bonding the masking wafer to the blanket wafer;
an alignment operation of aligning and bonding a plurality of LED dies onto the blanket wafer using the masking holes of the masking wafer;
a first removal operation of removing the masking wafer;
a second bonding operation of aligning the plurality of the LED dies onto the plurality of CMOS panel electrode dies by bonding the blanket wafer, on which the plurality of LED dies are aligned, to the back wafer; and
a second removal operation of removing the blanket wafer.

6. The method of claim 5, further comprising, after the second removal operation, a fabrication (FAB) operation of removing a support substrate of the LED die and forming a device structure for each pixel unit.

7. The method of claim 5, wherein, in the alignment operation, after pretreating the blanket wafer, the LED die is aligned and bonded onto the blanket wafer, and in the first bonding operation, after pretreating at least one of the blanket wafer and the back wafer, the blanket wafer is bonded to the back wafer.

8. The method of claim 5, wherein a size of the masking hole is greater than or equal to a size of the LED die.
